(19) United States
(12) Patent Application Publication
(10) Pub. No.: US 2014/0138615 A1
(43) Pub. Date: May 22, 2014

(54) LIGHT EMITTING DIODE

(71) Applicant: Advanced Optoelectronic Technology, Inc., Hsinchu Hsien (TW)

(72) Inventors: CHIA-HUI SHEN, Hsinchu (TW); TZU-CHIEN HUNG, Hsinchu (TW)

(73) Assignee: ADVANCED OPTOELECTRONIC TECHNOLOGY, INC., Hsinchu Hsien (TW)

(21) Appl. No.: 13/950,262

(22) Filed: Jul. 24, 2013

(30) Foreign Application Priority Data
Nov. 20, 2012 (CN) 2012104712152

(51) Int. Cl. H01L 33/38

(52) U.S. Cl. CPC H01L 33/385
USPC 257/13

(57) ABSTRACT

An LED includes a base and an LED die grown on the base. The LED die includes two spaced electrodes and two exposed semiconductor layers. The two electrodes are respectively formed on top surfaces of the two semiconductor layers. At least one of the electrodes extends downwardly from the top surface of the corresponding semiconductor layer along a lateral edge of the LED die to electrically connect an exterior electrode via transparent conducting resin.

### BACKGROUND

1. Technical Field

The present disclosure relates to semiconductor devices and, more particularly, to a light emitting diode (LED).

2. Description of Related Art

In recent years, LEDs have been widely used in devices to provide illumination. Typically, an LED may include an LED die, an electrode layer, and two gold wires. The LED die may include a light emitting surface. Two spaced terminals may be formed on the light emitting surface. The LED die may be electrically connected to the electrode layer through wire bonding, in which the two gold wires may be respectively soldered to the terminals and the electrode layer. However, part of the light emitting surface of the LED die may be blocked by the solder joint and the gold wires, resulting in a decreased illumination efficiency of the LED.

Accordingly, it is desirable to provide an LED which can overcome the described limitations.

### BRIEF DESCRIPTION OF THE DRAWINGS

FIG. 1 is a top view of an LED according to a first embodiment of the present disclosure.

FIG. 2 is a cross sectional view of the LED of FIG. 1, taken along II-II line thereof.

FIG. 3 is similar to the FIG. 2, further with the LED electrically connecting to exterior electrodes.

FIG. 4 is a top view of an LED according to a second embodiment of the present disclosure.

FIG. 5 is a cross sectional view of the LED of FIG. 4, taken along V-V line thereof.

FIG. 6 is similar to the FIG. 5, further with the LED electrically connecting exterior electrodes.

FIG. 7 is a cross sectional view of an LED according to a third embodiment of the present disclosure, wherein the LED electrically connects exterior electrodes.

### DETAILED DESCRIPTION

Embodiments of an LED will now be described in detail below and with reference to the drawings.

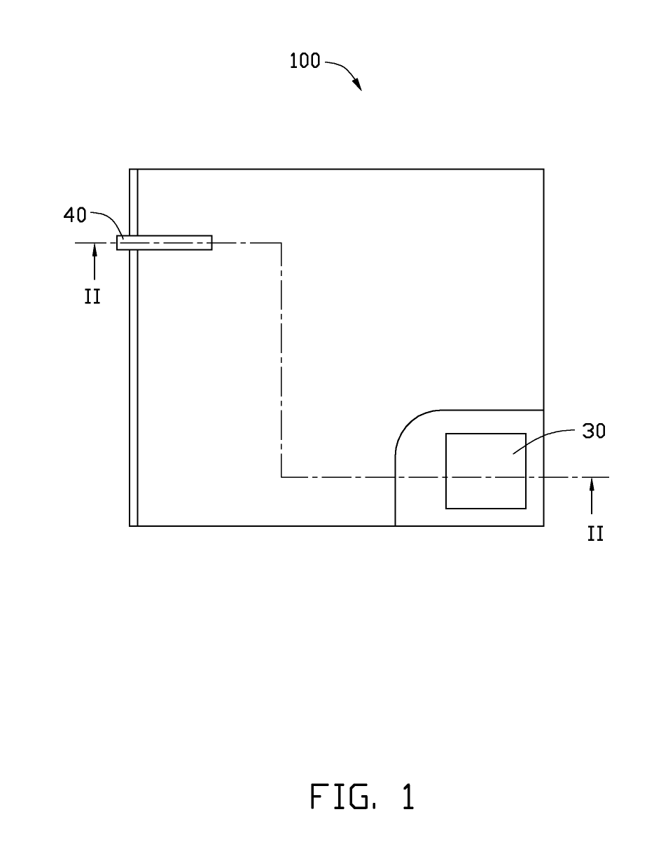

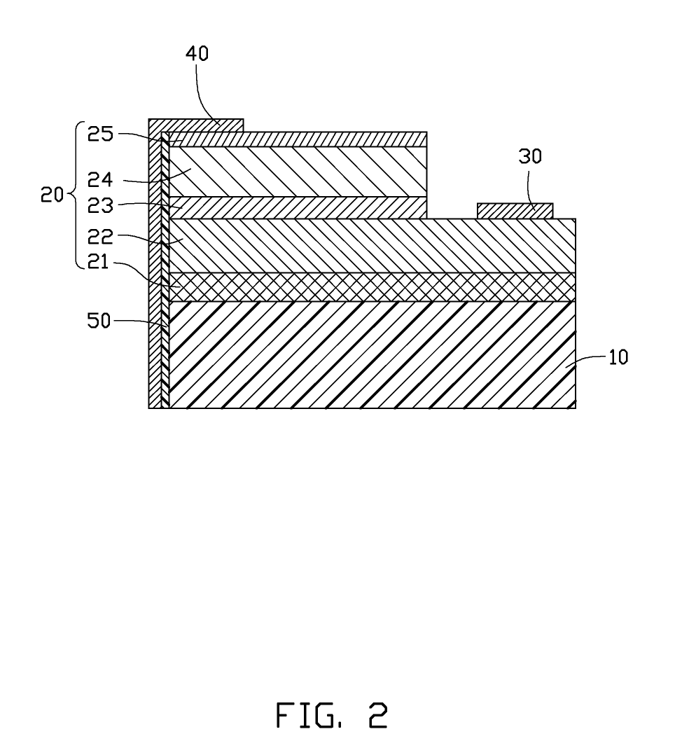

Referring to FIGS. 1-2, an LED 100 according to a first embodiment is shown. The LED 100 includes a base 10, an LED die 20 grown on the base 10, an N-type electrode 30 and a P-type electrode 40 formed on the LED die 20.

The base 11 is made of sapphire, SiC, Si, GaAs, LiAlO₂, MgO, ZnO, GaN, AlO, or InN.

The LED die 20 includes a buffer layer 21 formed on a top surface of the base 10, an N-doped region 22 formed on a top surface of the buffer layer 21, an active layer 23 formed on a top surface the N-doped region 22, a P-doped region 24 formed on a top surface of the active layer 23, and an electrically conductive layer 25 formed on a top surface of the P-doped region 24. The buffer layer 21 has a size equal to that of the base 10 and covers the whole of the top surface of the base 10. The N-doped region 22 has a size equal to that of the buffer layer 21 and covers the whole of the top surface of the buffer layer 21. The active layer 23 covers a left side portion of the top surface of the N-doped region 22 to expose a right side portion of the top surface of the N-doped region 22. The P-doped region 24 covers the whole of the top surface of the active layer 23. The electrically conductive layer 25 covers the whole of the top surface of the P-doped region 24.

The buffer layer 21 is used to decrease crystal lattices dislocation of the N-doped region 22 and improve a quality of the N-doped region 22. In this embodiment, the buffer layer 21 is made of GaN, AlGaN, AN, or InGaN. The active layer 23 includes a single quantum well structure, a multiple quantum well structure, and/or quantum dot structure. The electrically conductive layer 25 is formed by evaporating or sputtering and made of Ni/Au, Indium Tin Oxide, Indium Zinc Oxide, Indium Tungsten Oxide, or Indium Gallium Oxide. The electrically conductive layer 25 is transparent. The right side of the top surface of the N-doped region 22 is exposed by etching.

The N-type electrode 30 is a metallic pad, and formed on the right side of the top surface of the N-doped region 22 by evaporating or sputtering.

The P-type electrode 40 is an L-shaped strip and extends from a left side portion of a top surface of the electrically conductive layer 25, and extends down along lateral edges of the LED die 20 and the base 10. In this embodiment, a bottom end of the P-type electrode 40 is coplanar with a bottom surface of the base 10. Alternatively, the P-type electrode 40 extends to the bottom surface of the base 10. The P-type electrode 40 is formed by evaporating or sputtering. An electrically insulating layer 50 is formed on the lateral edges of the LED die 20 and the base 10 to isolate the lateral edge of the LED die 20 from the P-type electrode 40. Thus, the LED die 20 insulates from the P-type electrode 40 except the electrically conductive layer 25.

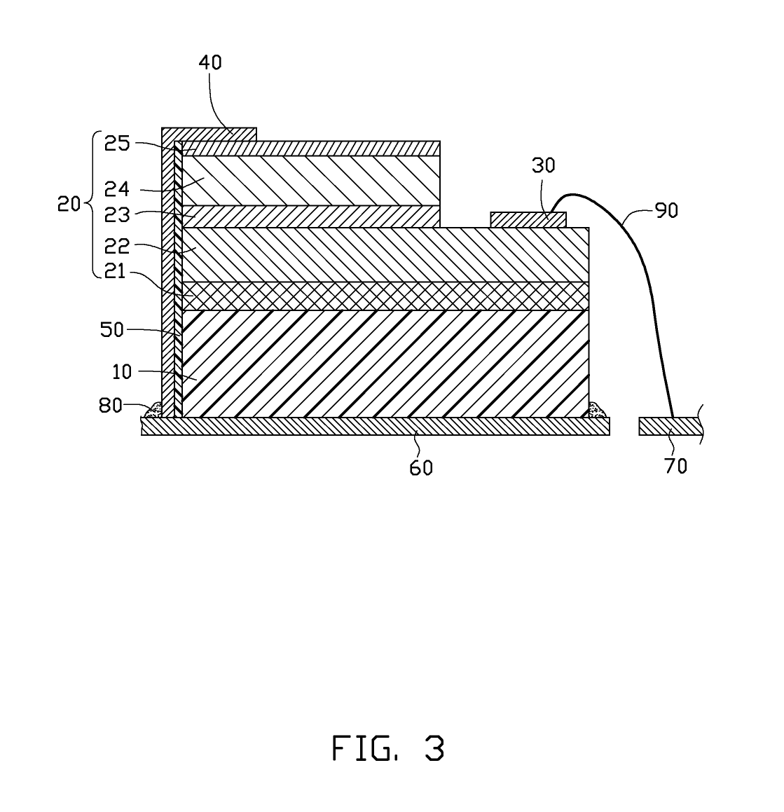

Referring to FIG. 3, when the LED 100 electrically connects an exterior power source, the bottom end of the P-type electrode 40 and the bottom surface of the base 10 are adhered to a first exterior electrode 60 via transparent conducting resin 80, and the N-type electrode 30 electrically connects a second exterior electrode 70 via opposite ends of a gold wire 90 respectively soldered on the N-type electrode 30 and the second exterior electrode 70.

In this embodiment, the P-type electrode 40 is an L-shaped strip and directly adhered to the first exterior electrode 60 by the transparent conducting resin 80, so the solder and the gold wire are not need to connect the P-type electrode 40 and the first exterior electrode 60. The P-type electrode 40 may be narrower relative to the conventional LED. Thus, a light emitting surface of the LED 100 blocked by the solder is decreased relative to the conventional LED, and an illumination efficiency of the LED 100 is improved.

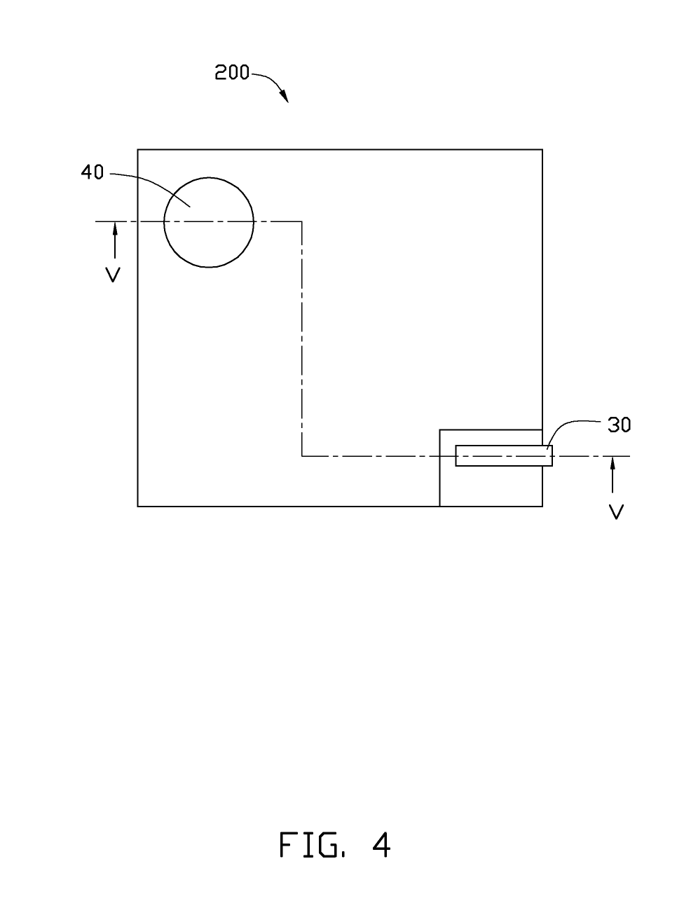

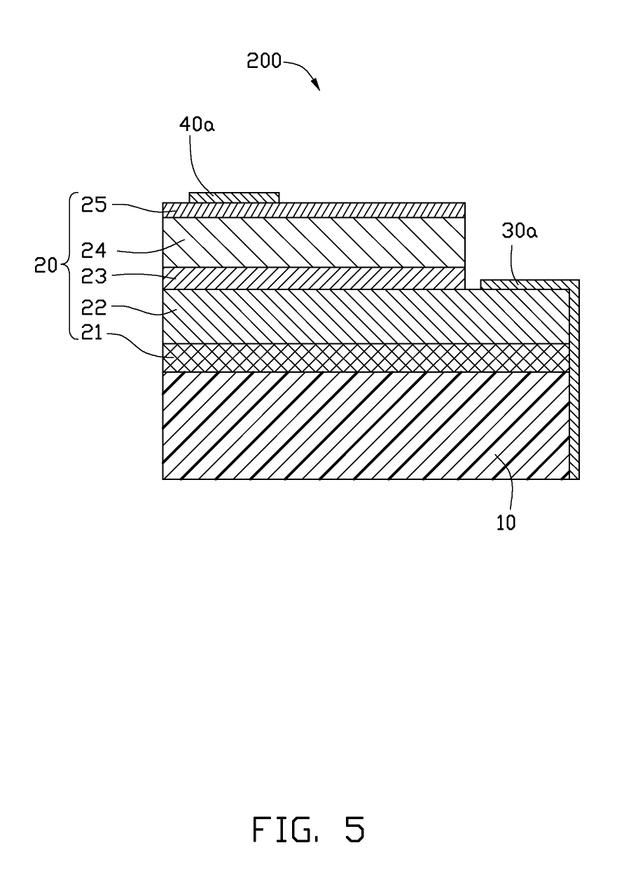

Referring to FIGS. 4-5, an LED 200 of a second embodiment is shown. The LED 200 is similar to the LED 100 of the first embodiment, and a difference therebetween is that a P-type electrode 40a of the LED 200 is a circular pad and formed on the top surface of the electrically conductive layer 25, and an N-type electrode 30a is an L-shaped strip, the N-type electrode 30a extends from outward the right side of the N-doped region 22, and extends down along lateral edges of the N-doped region 22, the buffer layer 21, and the base 10. A bottom end of the N-type electrode 30a is coplanar to the bottom surface of the base 10.

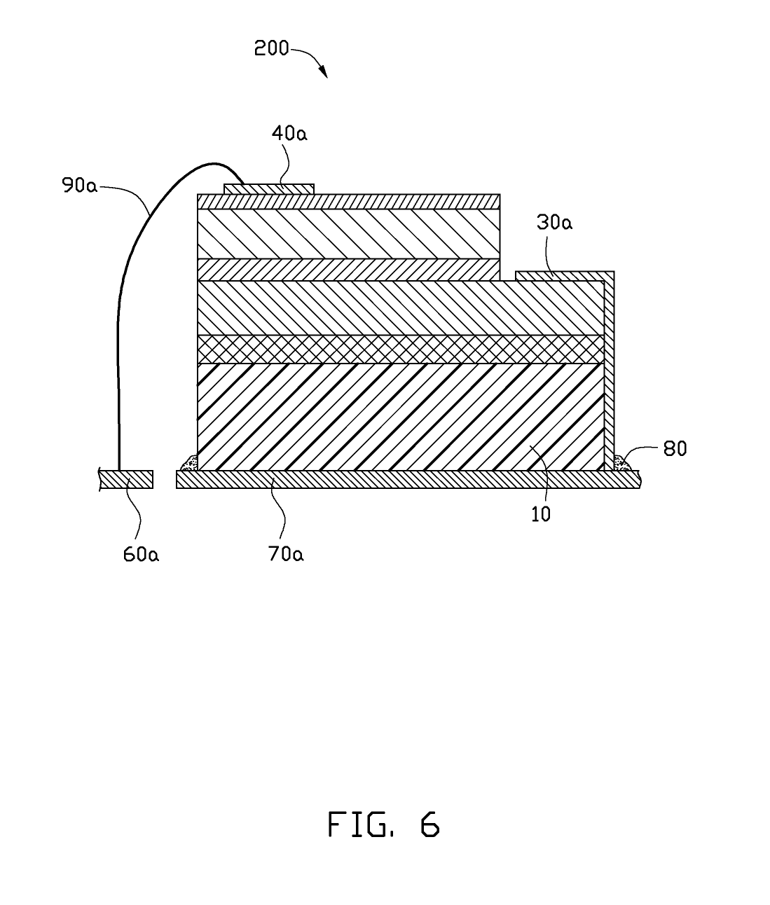

Referring to FIG. 6, when the LED 200 electrically connects an exterior power source, the bottom end of the N-type electrode 30a and the bottom surface of the base 10 are adhered to a second exterior electrode 70a by the transparent conducting resin 80, and the P-type electrode 40a electrically connects a first exterior electrode 60a through wire boding by a gold wire 90a.

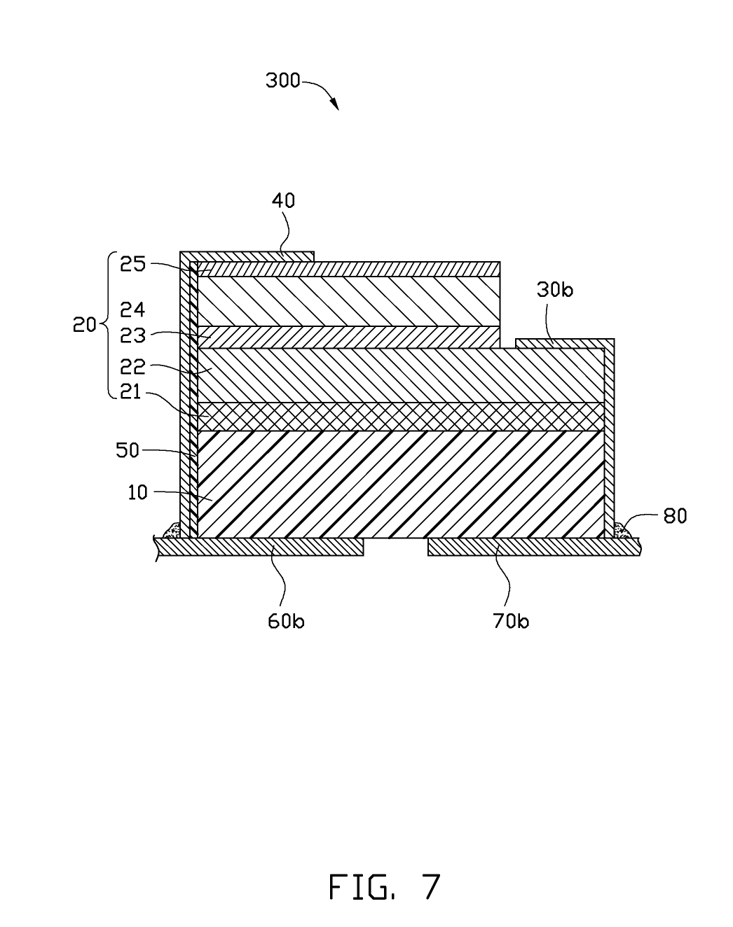

Referring to FIG. 7, an LED 300 of a third embodiment is shown. The LED 300 is similar to the LED 100 of the first embodiment, and a difference therebetween is that an N-type electrode 30b of the LED 300 is an L-shaped strip. The N-type electrode 30b extends from outward the right side of the N-doped region 22, and extends down along lateral edges of the N-doped region 22, the buffer layer 21, and the base 10. A bottom end of the N-type electrode 30b is coplanar to the bottom surface of the base 10. The bottom ends of the P-type electrode 40 and the N-type electrode 30b are respectively adhered to a first exterior electrode 60b and a second exterior electrode 70b. The first exterior electrode 60b and the second exterior electrode 70b are attached to the bottom surface of the base 10 and are spaced from each other.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A light emitting diode (LED) comprising:
a base; and
an LED die grown on the base, the LED die comprising two spaced electrodes and two exposed semiconductor layers, the two electrodes respectively formed on top surfaces of the semiconductor layers;
wherein at least one of the electrodes extends downwardly from the top surface of the corresponding semiconductor layer along a lateral edge of the LED die to electrically connect an exterior electrode via transparent conducting resin.

2. The LED of claim 1, wherein the semiconductor layers are an N-doped region and a P-doped region, the two electrodes are an N-type electrode and a P-type electrode, the LED die further comprises a buffer layer formed on a top surface of the base, the N-doped region formed on a top surface of the buffer layer, an active layer formed on a top surface of the N-doped region, the P-doped region formed on a top surface of the active layer, and the N-type electrode and the P-type electrode are respectively formed on top surfaces of the N-doped region and the P-doped region.

3. The LED of claim 2, wherein the LED die further comprises an electrically conductive layer formed on the top surface of the P-doped region, and the P-type electrode is formed on a top surface of the electrically conductive layer.

4. The LED of claim 3, wherein the P-type electrode is an L-shaped strip, and the P-type electrode extends outwardly from the top surface of the electrically conductive layer and downwardly along the lateral edge of the LED die to make a bottom end of the P-type electrode connect the exterior electrode.

5. The LED of claim 4, wherein an electrically insulating layer is formed on the lateral edges of the LED die to isolate the lateral edge of the LED die from the P-type electrode.

6. The LED of claim 4, wherein the N-type electrode is a metallic pad and mounted on the top surface of the N-doped region.

7. The LED of claim 4, wherein the N-type electrode is an L-shaped strip, the N-type electrode extends outwardly from the top surface of the N-doped region and downwardly along the lateral edge of the LED die to make a bottom end of the N-type electrode connect the exterior electrode.

8. The LED of claim 3, wherein the P-type electrode is a metallic pad and mounted on the top surface of the P-doped region, the N-type electrode is an L-shaped strip, and the N-type electrode extends outwardly from the top surface of the N-doped region and downwardly along the lateral edge of the LED die to make a bottom end of the N-type electrode connect the exterior electrode.

9. The LED of claim 3, wherein the electrically conductive layer is formed by evaporating or sputtering and made of Ni/Au, Indium Tin Oxide, Indium Zinc Oxide, Indium Tungsten Oxide, or Indium Gallium Oxide.

10. The LED of claim 3, wherein the buffer layer is made of GaN, AlGaN, AN, or InGaN.

11. The LED of claim 3, wherein the active layer comprises a single quantum well structure

12. The LED of claim 3, wherein the N-type electrode and the P-type electrode are formed by evaporating or sputtering.

13. The LED of claim 1, wherein the exterior electrode is attached to a bottom surface of the base.
